(19) United States
(12) Patent Application Publication
(10) Pub. No.: US 2026/0322399 A1
(43) Pub. Date: Oct. 15, 2026

(54) PROGRESSIVE CODING FOR BANDWIDTH COMPRESSION

(71) Applicant: QUALCOMM Incorporated, San Diego, CA (US)

(72) Inventors: Hyung Joon KIM, San Diego, CA (US); Venkata Meher Satchit Anand KOTRA, Munich (DE); Huai-Nan PENG, Miaoli City (TW); Cheng-Teh HSIEH, Del Mar, CA (US); Wei-Jung CHIEN, San Diego, CA (US); Marta KARCZEWICZ, San Diego, CA (US); Andrew Edmund TURNER, San Diego, CA (US); Natan JACOBSON, San Diego, CA (US)

(21) Appl. No.: 19/179,941

(22) Filed: Apr. 15, 2025

(51) Int. Cl. H03M 7/30

(52) U.S. Cl. CPC H03M 7/3071; H03M 7/6005; H03M 7/6011

(57) ABSTRACT

This disclosure provides systems, devices, apparatus, and methods, including computer programs encoded on storage media, for performing progressive coding on a set of surface data. A graphics processor may obtain a set of surface data. The graphics processor may truncate the obtained set of surface data to remove a set of least significant bits (LSBs). The graphics processor may select a subset of the removed set of LSBs based on an optimization parameter. The graphics processor may output a representation of the truncated set of surface data and a set of pulse code modulation (PCM) bits indicating the selected subset of the removed set of LSBs. The graphics processor may perform progressive decoding on the representation of the truncated set of surface data and the set of PCM bits indicating the selected subset of the removed set of LSBs to reconstruct the set of surface data.

### TECHNICAL FIELD

The present disclosure relates generally to processing systems, and more particularly, to one or more techniques for graphics processing.

### INTRODUCTION

Computing devices often perform graphics and/or display processing (e.g., utilizing a graphics processing unit (GPU), a central processing unit (CPU), a display processor, etc.) to render and display visual content. Such computing devices may include, for example, computer workstations, mobile phones such as smartphones, embedded systems, personal computers, tablet computers, and video game consoles. GPUs are configured to execute a graphics processing pipeline that includes one or more processing stages, which operate together to execute graphics processing commands and output a frame. A central processing unit (CPU) may control the operation of the GPU by issuing one or more graphics processing commands to the GPU. Modern day CPUs are typically capable of executing multiple applications concurrently, each of which may need to utilize the GPU during execution. A display processor may be configured to convert digital information received from a CPU to analog values and may issue commands to a display panel for displaying the visual content. A device that provides content for visual presentation on a display may utilize a CPU, a GPU, and/or a display processor.

Current techniques may not address providing multiple layers of lossy compression algorithms to optimize performance at graphics processors. There is a need for improved compression techniques.

### BRIEF SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided. The apparatus may include a memory; and a set of processors coupled to the memory and, based at least in part on information stored in the memory, the set of processors may be configured to obtain a set of surface data. The set of processors may truncate the obtained set of surface data to remove a set of least significant bits (LSBs). The set of processors may select a subset of the removed set of LSBs based on an optimization parameter. The set of processors may output a representation of the truncated set of surface data and a set of pulse code modulation (PCM) bits indicating the selected subset of the removed set of LSBs.

In some aspects, the techniques described herein relate to a method of graphics processing, including: obtaining a set of surface data; truncating the obtained set of surface data to remove a set of least significant bits (LSBs); selecting a subset of the removed set of LSBs based on an optimization parameter; and outputting a representation of the truncated set of surface data and a set of pulse code modulation (PCM) bits indicating the selected subset of the removed set of LSBs.

In some aspects, the techniques described herein relate to a method, further including: selecting the optimization parameter from a plurality of optimization parameters based on a distortion and a rate associated with each corresponding optimization parameter of the plurality of optimization parameters.

In some aspects, the techniques described herein relate to a method, further including: receiving an indication of a tuning parameter, where selecting the optimization parameter from the plurality of optimization parameters further includes: selecting the optimization parameter from the plurality of optimization parameters further based on the received indication of the tuning parameter.

In some aspects, the techniques described herein relate to a method, where selecting the optimization parameter from the plurality of optimization parameters further based on the received indication of the tuning parameter includes: determining a cost for each optimization parameter of the plurality of optimization parameters based on the distortion, the rate, and the tuning parameter; and selecting the optimization parameter based on the determined cost for each optimization parameter of the plurality of optimization parameters.

In some aspects, the techniques described herein relate to a method, further including: obtaining a second set of surface data; truncating the obtained second set of surface data to remove a second set of least significant bits (LSBs); and outputting a second representation of the obtained second set of surface data based on a determination that a size of the truncated second set of surface data does not satisfy a PCM threshold size.

In some aspects, the techniques described herein relate to a method, where outputting the representation of the truncated set of surface data and the set of PCM bits includes: outputting a bitstream including a progressive coding (PC) PC header, the representation of the truncated set of surface data, and the set of PCM bits, where the PC header includes an indication of the optimization parameter.

In some aspects, the techniques described herein relate to a method, where selecting the subset of the removed set of LSBs based on the optimization parameter includes: obtaining an indication of a first priority associated with a first tile of the set of surface data and an indication of a second priority associated with a second tile of the set of surface data; and selecting a first optimization parameter associated with the first tile based on the first priority and a second optimization parameter associated with the second tile based on the second priority, where the first optimization parameter is associated with a different number of removed LSBs than the second optimization parameter.

In some aspects, the techniques described herein relate to a method, where the set of PCM bits are not entropy encoded.

In some aspects, the techniques described herein relate to a method, further including: entropy encoding the truncated set of surface data before outputting the representation of the truncated set of surface data.

In some aspects, the techniques described herein relate to a method, further including: refraining from entropy encoding the set of PCM bits.

In some aspects, the techniques described herein relate to a method, further including: performing prediction on the truncated set of surface data before entropy encoding the truncated set of surface data.

In some aspects, the techniques described herein relate to a method of graphics processing, including: obtaining a representation of a truncated set of surface data and a set of pulse code modulation (PCM) bits indicating a subset of a removed set of LSBs; decompressing the obtained representation of the truncated set of surface data; reconstructing a set of LSBs based on the obtained set of PCM bits; and reconstructing a set of surface data based on the decompressed representation of the truncated set of surface data and the reconstructed set of LSBs.

In some aspects, the techniques described herein relate to a method, further including: obtaining a second representation of a second set of surface data, where the second representation does not comprise compressed data.

In some aspects, the techniques described herein relate to a method, where obtaining the representation of the truncated set of surface data and the set of PCM bits includes: obtaining a bitstream comprising a progressive coding (PC) PC header, the representation of the truncated set of surface data, and the set of PCM bits, where the PC header includes an indication of an optimization parameter, where reconstructing the set of LSBs based on the obtained set of PCM bits includes: reconstructing the set of LSBs further based on the optimization parameter.

In some aspects, the techniques described herein relate to a method, where the optimization parameter indicates a number of bitplanes per subtile of the bitstream, where reconstructing the set of LSBs further based on the optimization parameter includes: reconstructing a number of bits equal to the number of bitplanes for each subtile of the bitstream.

In some aspects, the techniques described herein relate to a method, further including: parsing the PC header to determine the indication of the optimization parameter before a reconstruction of the set of LSBs.

In some aspects, the techniques described herein relate to a method, further including: entropy decoding the obtained representation of the truncated set of surface data before a decompression of the obtained representation of the truncated set of surface data.

In some aspects, the techniques described herein relate to a method, further including: refraining from entropy decoding the obtained set of PCM bits.

To the accomplishment of the foregoing and related ends, the one or more aspects include the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a block diagram that illustrates an example content generation system in accordance with one or more techniques of this disclosure.

FIG. 2 illustrates an example graphics processor, in accordance with one or more techniques of this disclosure.

FIG. 3 illustrates an example graphics processor, in accordance with one or more techniques of this disclosure.

FIG. 4 illustrates an example progressive coding (PC) encoder, in accordance with one or more techniques of this disclosure.

FIG. 5 illustrates an example PC encoder, in accordance with one or more techniques of this disclosure.

FIG. 6 illustrates an example PC encoder, in accordance with one or more techniques of this disclosure.

FIG. 7 illustrates exemplary input and output bitstreams for a PC encoder, in accordance with one or more techniques of this disclosure.

FIG. 8 illustrates an example PC decoder, in accordance with one or more techniques of this disclosure.

FIG. 9 is a call flow diagram illustrating example communications between a PC encoder and a PC decoder in accordance with one or more techniques of this disclosure.

FIG. 10 is a flowchart of an example method of graphics processing in accordance with one or more techniques of this disclosure.

FIG. 11 is a flowchart of an example method of graphics processing in accordance with one or more techniques of this disclosure.

FIG. 12 is a flowchart of an example method of graphics processing in accordance with one or more techniques of this disclosure.

### DETAILED DESCRIPTION

Various aspects of systems, apparatuses, computer program products, and methods are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of this disclosure to those skilled in the art. Based on the teachings herein one skilled in the art should appreciate that the scope of this disclosure is intended to cover any aspect of the systems, apparatuses, computer program products, and methods disclosed herein, whether implemented independently of, or combined with, other aspects of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. Any aspect disclosed herein may be embodied by one or more elements of a claim.

Although various aspects are described herein, many variations and permutations of these aspects fall within the scope of this disclosure. Although some potential benefits and advantages of aspects of this disclosure are mentioned, the scope of this disclosure is not intended to be limited to particular benefits, uses, or objectives. Rather, aspects of this disclosure are intended to be broadly applicable to different wireless technologies, system configurations, processing systems, networks, and transmission protocols, some of which are illustrated by way of example in the figures and in the following description. The detailed description and drawings are merely illustrative of this disclosure rather than limiting, the scope of this disclosure being defined by the appended claims and equivalents thereof.

Several aspects are presented with reference to various apparatus and methods. These apparatus and methods are described in the following detailed description and illustrated in the accompanying drawings by various blocks, components, circuits, processes, algorithms, and the like (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors (which may also be referred to as processing units). Examples of processors include microprocessors, microcontrollers, graphics processing units (GPUs), general purpose GPUs (GPGPUs), central processing units (CPUs), application processors, digital signal processors (DSPs), reduced instruction set computing (RISC) processors, systems-on-chip (SOCs), baseband processors, application specific integrated circuits (ASICs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software can be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

The term application may refer to software. As described herein, one or more techniques may refer to an application (e.g., software) being configured to perform one or more functions. In such examples, the application may be stored in a memory (e.g., on-chip memory of a processor, system memory, or any other memory). Hardware described herein, such as a processor may be configured to execute the application. For example, the application may be described as including code that, when executed by the hardware, causes the hardware to perform one or more techniques described herein. As an example, the hardware may access the code from a memory and execute the code accessed from the memory to perform one or more techniques described herein. In some examples, components are identified in this disclosure. In such examples, the components may be hardware, software, or a combination thereof. The components may be separate components or sub-components of a single component.

In one or more examples described herein, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can include a random access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

As used herein, instances of the term “content” may refer to “graphical content,” an “image,” etc., regardless of whether the terms are used as an adjective, noun, or other parts of speech. In some examples, the term “graphical content,” as used herein, may refer to a content produced by one or more processes of a graphics processing pipeline. In further examples, the term “graphical content,” as used herein, may refer to a content produced by a processing unit configured to perform graphics processing. In still further examples, as used herein, the term “graphical content” may refer to a content produced by a graphics processing unit.

The following description is directed to examples for the purposes of describing innovative aspects of this disclosure. However, a person having ordinary skill in the art may recognize that the teachings herein may be applied in a multitude of ways. Some or all of the described examples may be implemented in any device or system that is capable of processing graphics commands. Various aspects relate generally to reprojecting and/or composing frames for a graphics processing unit (GPU). Some aspects more specifically relate to applying reprojection fallback strategies during an excess system load (e.g., when a reprojection process for a frame will not complete in time to display the frame). For example, a graphics system may have limited dynamic random-access memory (DRAM) bandwidth due to concurrent work (e.g., rendering, GPU workload, high-intensity periods of camera data acquisition), software control latencies (e.g., poorly optimized code, latencies when communicating with third-party applications), bottlenecking hardware execution, and/or power/thermal throttling. Such loads may affect the calculated projected time for a reprojection process to complete within a threshold period of time. Use of remotely rendered framebuffers (e.g., frames processed by a reprojection topology on a separate system, or a third-party system), may also affect the time to render a frame. For example, use of a second reprojection process may conserve resources if a first reprojection process uses remote-rendered framebuffers having a high calculated latency value, or if a first reprojection process uses a large amount of bandwidth (e.g., WiFi, 5G bandwidth) and a system is configured to conserve use of that bandwidth with respect to transmission/reception of remote-rendered frames.

In some aspects, a progressive coding (PC) engine may improve the coding efficiency of a lossy bandwidth compression algorithm by leveraging a progressive refinement scheme at the encoder to determine whether to add refinement bits to the bitstream, and how many refinement bits to add to the bitstream to optimize the efficiency of the compression. A progressive refinement scheme is one that may encode, or compress, a set of surface data incrementally, such that primary bits of a bitstream may include a full set of tiles for the set of surface data, and later bits of the bitstream may improve the resolution to the full set of tiles. In other words, the primary bits may be used to reconstruct a full surface while the later bits may improve the resolution of the full surface. The later bits that may be used to improve the resolution of the full surface may be referred to as refinement bits. The more refinement bits that an encoder adds to a bitstream, the higher the quality of the reconstructed surface. The encoder may leverage rate-distortion optimization (RDO) techniques to determine an efficient number of refinement bits for each tile of a surface based on a tradeoff between rate and distortion. A surface may be logically divided into a plurality of tiles that cover the surface. An encoder of a PC engine may be configured to optimally determine the efficient number of refinement bits. The encoder of the PC engine may quantize a set of source data, or surface data, using a specified quantization factor, which may also be referred to as QP_{pc}. The encoder of the PC engine may perform prediction and entropy coding on the truncated samples to generate a base bitstream. A decoder of a PC engine may decode, or decompress, the base bitstream to reconstruct a full surface tile by tile. However, a surface reconstructed using the base bitstream may be lossy, or have a low resolution. The base bitstream may include entropy-encoded samples as well as headers and syntax for a full set of surface data. If the base bitstream is greater than or equal to a threshold value (e.g., 1024 bits), then the encoder of the PC engine may fall back to transmitting the raw set of surface data without a compression scheme applied. This ensures that a minimum rate constraint is followed. If the base bitstream is less than or equal to the threshold value, then the encoder of the PC engine may perform PC refinement to determine an optimal number of refinement bits to add to the bitstream. The encoder of the PC engine may calculate a distortion created by the original quantization (i.e., for the base bitstream) by the specified quantization factor. The encoder of the PC engine may select a quantity of bitplanes to send as refinement bits at the end of the syntax. A bitplane may be a layer of bits located at a tail end of a base bitstream of a subtile. A subtile may be a defined portion of a tile. A tile may be separated into a plurality of subtiles via spatial partitioning of the tile, or via splitting the tile into its constituent components. As an example, for a red, green, blue, alpha, 8-bit (RGBA8888) format may partition a tile into four color components within the tile, where each tile corresponds to one of the four colors red, green, blue, or alpha. The combination of the base bitstream and the refinement bits added to the base bitstream may be referred to as a refined bitstream. The encoder of the PC engine may select between transmitting refined bitstreams having different numbers of bitplanes based on the rate distortion (RD) cost of each optional refined bitstream.

In some examples, a PC engine of a graphics processor (or graphics processor system) may be configured to encode a set of data. The PC engine may obtain a set of surface data. The set of surface data may include image or pixel data to be displayed on a surface, for example a surface of a rendered primitive or a surface of a display. The PC engine may truncate the obtained set of surface data to remove a set of least significant bits (LSBs). A decoder may reconstruct a lossy full set of surface data using the truncated set of surface data. The PC engine may select a subset of the removed set of LSBs based on an optimization parameter. The optimization parameter may indicate an optimized number of bitplanes to add to the truncated set of surface data. The PC engine may output a representation of the truncated set of surface data and a set of pulse code modulation (PCM) bits indicating the selected subset of the removed set of LSBs. The truncated set of surface data may also be referred to as a base bitstream. PCM bits may be bits signaled directly in the bitstream without any entropy encoding applied. The set of PCM bits may also be referred to as PC refinement bits.

The PC engine may select the optimization parameter from a plurality of optimization parameters based on a distortion (D) and a rate (R) associated with each corresponding optimization parameter of the plurality of optimization parameters. A distortion may be expressed based on a calculated difference between the original signal and quantized/reconstructed signal, or an output bitstream, of an encoder. The PC engine may receive an indication of a tuning parameter (λ). The tuning parameter may be used to adjust a trade-off between optimizing for a lower rate or optimizing for a lower distortion. To select the optimization parameter from the plurality of optimization parameters, the PC engine may select the optimization parameter from the plurality of optimization parameters further based on the received indication of the tuning parameter. In other words, the received indication may increase the value of lowering the rate as compared to lowering the distortion, or the received indication may increase the value of lowering the distortion as compared to lowering the rate. To select the optimization parameter from the plurality of optimization parameters further based on the received indication of the tuning parameter, the PC engine may determine a cost for each optimization parameter of the plurality of optimization parameters based on the distortion, the rate, and the tuning parameter. For example, the cost (C) may be calculated as C=D+λ×R, where D represents the amount of distortion of the base bitstream by itself, R represents the rate (i.e., total size in bits of the compressed, or processed, bitstream), and λ represents a user-defined parameter for rate distortion (RD) point control. R may be calculated as the number of bits for the base bitstream plus the number of refinement bits. To select the optimization parameter from the plurality of optimization parameters further based on the received indication of the tuning parameter, the PC engine may select the optimization parameter based on the determined cost for each optimization parameter of the plurality of optimization parameters. For example, the PC engine may select the optimization parameter associated with the lowest determined cost. The PC engine may obtain a second set of surface data. The PC engine may truncate the obtained second set of surface data to remove a second set of LSBs. The PC engine may output a second representation of the obtained second set of surface data based on a determination that a size of the truncated second set of surface data does not satisfy a PCM threshold size. For example, in response to determining that the truncated second set of surface data is too large to fit within an allocated PCM size (e.g., greater than or equal to a PCM threshold size), the PC engine may output a fallback PCM tile, for example by outputting a PCM tile that includes the most significant bit (MSB) half of the tile and does not include the LSB half of the tile. To output the representation of the truncated set of surface data and the set of PCM bits, the PC engine may output a bitstream including a PC header, the representation of the truncated set of surface data, and the set of PCM bits. The PC header may include an indication of the optimization parameter. In other words, the PC header may include a field that may be used to indicate a number of refinement bits. To select the subset of the removed set of LSBs based on the optimization parameter, the PC engine may obtain an indication of a first priority associated with a first tile of the set of surface data and an indication of a second priority associated with a second tile of the set of surface data. To select the subset of the removed set of LSBs based on the optimization parameter, the PC engine may select a first optimization parameter associated with the first tile based on the first priority and may select a second optimization parameter associated with the second tile based on the second priority. The first optimization parameter may be associated with a different number of removed LSBs than the second optimization parameter. In other words, the refined bitstream of a higher priority tile may have more refinement bits than the refined bitstream of a comparatively lower priority tile. The PC engine may entropy encode the truncated set of surface data before outputting the representation of the truncated set of surface data. The PC engine may refrain from entropy encoding the set of PCM bits, also referred to as the refinement bits. The PC engine may perform prediction on the truncated set of surface data before entropy encoding the truncated set of surface data.

In some examples, a PC engine of a graphics processor (or graphics processor system) may be configured to decode a set of encoded data. The PC engine may obtain a representation of a truncated set of surface data and a set of PCM bits indicating a subset of a removed set of LSBs. For example, the PC engine may receive a bitstream having a refined bitstream with a base bitstream and refinement bits. The PC engine may decompress the obtained representation of the truncated set of surface data. The PC engine may reconstruct a set of LSBs based on the obtained set of PCM bits. The PC engine may reconstruct a set of surface data based on the decompressed representation of the truncated set of surface data and the reconstructed set of LSBs.

The PC engine may obtain a second representation of a second set of surface data, where the second representation does not comprise compressed data. The PC engine may obtain a bitstream comprising a progressive coding (PC) PC header, the representation of the truncated set of surface data, and the set of PCM bits, where the PC header comprises an indication of an optimization parameter. To reconstruct the set of LSBs based on the obtained set of PCM bits, the PC engine may reconstruct the set of LSBs further based on the optimization parameter. The optimization parameter may indicate a number of bitplanes per subtile of the bitstream. To reconstruct the set of LSBs further based on the optimization parameter, the PC engine may reconstruct a number of bits equal to the number of bitplanes for each subtile of the bitstream. The PC engine may parse the PC header to determine the indication of the optimization parameter before a reconstruction of the set of LSBs. The PC engine may entropy decode the obtained representation of the truncated set of surface data before a decompression of the obtained representation of the truncated set of surface data. The PC engine may refrain from entropy decoding the obtained set of PCM bits.

Particular aspects of the subject matter described in this disclosure can be implemented to realize one or more of the following potential advantages. In some examples, by leveraging a progressive refinement scheme at the encoder to add an efficient number of refinement bits to a base bitstream, the described techniques can be used to improve compression performance based on a calculated RD cost.

The examples describe herein may refer to a use and functionality of a graphics processing unit (GPU). As used herein, a GPU can be any type of graphics processor, and a graphics processor can be any type of processor that is designed or configured to process graphics content. For example, a graphics processor or GPU can be a specialized electronic circuit that is designed for processing graphics content. As an additional example, a graphics processor or GPU can be a general-purpose processor that is configured to process graphics content.

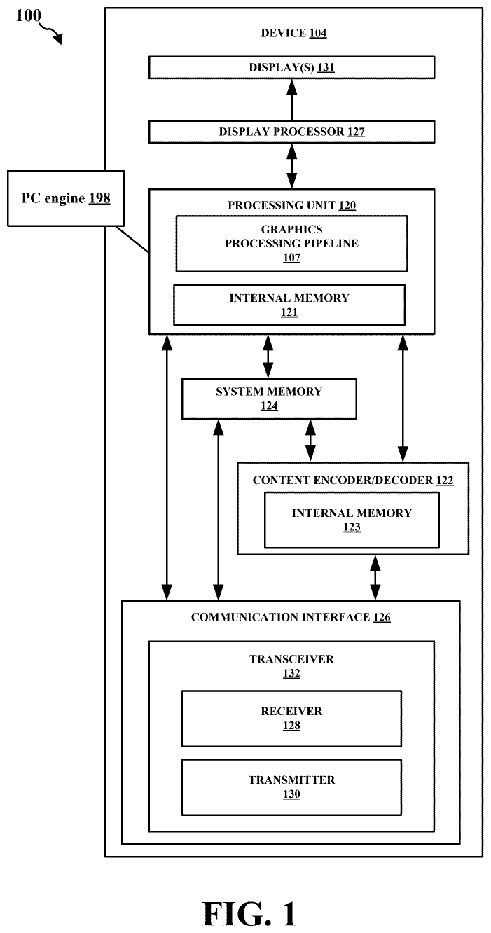

FIG. 1 is a block diagram that illustrates an example content generation system 100 configured to implement one or more techniques of this disclosure. The content generation system 100 includes a device 104. The device 104 may include one or more components or circuits for performing various functions described herein. In some examples, one or more components of the device 104 may be components of a SOC. The device 104 may include one or more components configured to perform one or more techniques of this disclosure. In the example shown, the device 104 may include a processing unit 120, a content encoder/decoder 122, and a system memory 124. In some aspects, the device 104 may include a number of components (e.g., a communication interface 126, a transceiver 132, a receiver 128, a transmitter 130, a display processor 127, and one or more displays 131). Display(s) 131 may refer to one or more displays 131. For example, the display 131 may include a single display or multiple displays, which may include a first display and a second display. The first display may be a left-eye display and the second display may be a right-eye display. In some examples, the first display and the second display may receive different frames for presentment thereon. In other examples, the first and second display may receive the same frames for presentment thereon. In further examples, the results of the graphics processing may not be displayed on the device, e.g., the first display and the second display may not receive any frames for presentment thereon. Instead, the frames or graphics processing results may be transferred to another device. In some aspects, this may be referred to as split-rendering.

The processing unit 120 may include an internal memory 121. The processing unit 120 may be configured to perform graphics processing using a graphics processing pipeline 107. The content encoder/decoder 122 may include an internal memory 123. In some examples, the device 104 may include a processor, which may be configured to perform one or more display processing techniques on one or more frames generated by the processing unit 120 before the frames are displayed by the one or more displays 131. While the processor in the example content generation system 100 is configured as a display processor 127, it should be understood that the display processor 127 is one example of the processor and that other types of processors, controllers, etc., may be used as substitute for the display processor 127. The display processor 127 may be configured to perform display processing. For example, the display processor 127 may be configured to perform one or more display processing techniques on one or more frames generated by the processing unit 120. The one or more displays 131 may be configured to display or otherwise present frames processed by the display processor 127. In some examples, the one or more displays 131 may include one or more of a liquid crystal display (LCD), a plasma display, an organic light emitting diode (OLED) display, a projection display device, an augmented reality display device, a virtual reality display device, a head-mounted display, or any other type of display device.

Memory external to the processing unit 120 and the content encoder/decoder 122, such as system memory 124, may be accessible to the processing unit 120 and the content encoder/decoder 122. For example, the processing unit 120 and the content encoder/decoder 122 may be configured to read from and/or write to external memory, such as the system memory 124. The processing unit 120 may be communicatively coupled to the system memory 124 over a bus. In some examples, the processing unit 120 and the content encoder/decoder 122 may be communicatively coupled to the internal memory 121 over the bus or via a different connection.

The content encoder/decoder 122 may be configured to receive graphical content from any source, such as the system memory 124 and/or the communication interface 126. The system memory 124 may be configured to store received encoded or decoded graphical content. The content encoder/decoder 122 may be configured to receive encoded or decoded graphical content, e.g., from the system memory 124 and/or the communication interface 126, in the form of encoded pixel data. The content encoder/decoder 122 may be configured to encode or decode any graphical content.

The internal memory 121 or the system memory 124 may include one or more volatile or non-volatile memories or storage devices. In some examples, internal memory 121 or the system memory 124 may include RAM, static random-access memory (SRAM), dynamic random-access memory (DRAM), erasable programmable ROM (EPROM), EEPROM, flash memory, a magnetic data media or an optical storage media, or any other type of memory. The internal memory 121 or the system memory 124 may be a non-transitory storage medium according to some examples. The term “non-transitory” may indicate that the storage medium is not embodied in a carrier wave or a propagated signal. However, the term “non-transitory” should not be interpreted to mean that internal memory 121 or the system memory 124 is non-movable or that its contents are static. As one example, the system memory 124 may be removed from the device 104 and moved to another device. As another example, the system memory 124 may not be removable from the device 104.

The processing unit 120 may be a CPU, a GPU, GPGPU, or any other processing unit that may be configured to perform graphics processing. In some examples, the processing unit 120 may be integrated into a motherboard of the device 104. In further examples, the processing unit 120 may be present on a graphics card that is installed in a port of the motherboard of the device 104, or may be otherwise incorporated within a peripheral device configured to interoperate with the device 104. The processing unit 120 may include one or more processors, such as one or more microprocessors, GPUs, ASICs, FPGAs, arithmetic logic units (ALUs), DSPs, discrete logic, software, hardware, firmware, other equivalent integrated or discrete logic circuitry, or any combinations thereof. If the techniques are implemented partially in software, the processing unit 120 may store instructions for the software in a suitable, non-transitory computer-readable storage medium, e.g., internal memory 121, and may execute the instructions in hardware using one or more processors to perform the techniques of this disclosure. Any of the foregoing, including hardware, software, a combination of hardware and software, etc., may be considered to be one or more processors. A set of processors configured to perform a set of tasks may be configured to perform the set of tasks individually, or in any combination.

The content encoder/decoder 122 may be any processing unit configured to perform content decoding. In some examples, the content encoder/decoder 122 may be integrated into a motherboard of the device 104. The content encoder/decoder 122 may include one or more processors, such as one or more microprocessors, application specific integrated circuits (ASICs), field programmable gate arrays (FPGAs), arithmetic logic units (ALUs), digital signal processors (DSPs), video processors, discrete logic, software, hardware, firmware, other equivalent integrated or discrete logic circuitry, or any combinations thereof. If the techniques are implemented partially in software, the content encoder/decoder 122 may store instructions for the software in a suitable, non-transitory computer-readable storage medium, e.g., internal memory 123, and may execute the instructions in hardware using one or more processors to perform the techniques of this disclosure. Any of the foregoing, including hardware, software, a combination of hardware and software, etc., may be considered to be one or more processors.

In some aspects, the content generation system 100 may include a communication interface 126. The communication interface 126 may include a receiver 128 and a transmitter 130. The receiver 128 may be configured to perform any receiving function described herein with respect to the device 104. Additionally, the receiver 128 may be configured to receive information, e.g., eye or head position information, rendering commands, and/or location information, from another device. The transmitter 130 may be configured to perform any transmitting function described herein with respect to the device 104. For example, the transmitter 130 may be configured to transmit information to another device, which may include a request for content. The receiver 128 and the transmitter 130 may be combined into a transceiver 132. In such examples, the transceiver 132 may be configured to perform any receiving function and/or transmitting function described herein with respect to the device 104.

Referring again to FIG. 1, in certain aspects, the processing unit 120 may include a PC engine 198 configured to encode a set of surface data. The PC engine 198 may be configured to obtain a set of surface data. The PC engine 198 may be configured to truncate the obtained set of surface data to remove a set of LSBs. The PC engine 198 may be configured to select a subset of the removed set of LSBs based on an optimization parameter. The PC engine 198 may be configured to output a representation of the truncated set of surface data and a set of PCM bits indicating the selected subset of the removed set of LSBs. In certain aspects, the processing unit 120 may include a PC engine 198 configured to decode a set of compressed data. The PC engine 198 may be configured to obtain a representation of a truncated set of surface data and a set of PCM bits indicating a subset of a removed set of LSBs. The PC engine 198 may be configured to decompress the obtained representation of the truncated set of surface data. The PC engine 198 may be configured to reconstruct a set of LSBs based on the obtained set of PCM bits. The PC engine 198 may be configured to reconstruct a set of surface data based on the decompressed representation of the truncated set of surface data and the reconstructed set of LSBs. Although the following description may be focused on graphics processing, the concepts described herein may be applicable to other similar processing techniques.

A device, such as the device 104, may refer to any device, apparatus, or system configured to perform one or more techniques described herein. For example, a device may be a server, a base station, a user equipment, a client device, a station, an access point, a computer such as a personal computer, a desktop computer, a laptop computer, a tablet computer, a computer workstation, or a mainframe computer, an end product, an apparatus, a phone, a smart phone, a server, a video game platform or console, a handheld device such as a portable video game device or a personal digital assistant (PDA), a wearable computing device such as a smart watch, an augmented reality device, or a virtual reality device, a non-wearable device, a display or display device, a television, a television set-top box, an intermediate network device, a digital media player, a video streaming device, a content streaming device, an in-vehicle computer, any mobile device, any device configured to generate graphical content, or any device configured to perform one or more techniques described herein. Processes herein may be described as performed by a particular component (e.g., a GPU) but in other embodiments, may be performed using other components (e.g., a CPU) consistent with the disclosed embodiments.

GPUs can process multiple types of data or data packets in a GPU pipeline. For instance, in some aspects, a GPU can process two types of data or data packets, e.g., context register packets and draw call data. A context register packet can be a set of global state information, e.g., information regarding a global register, shading program, or constant data, which can regulate how a graphics context will be processed. For example, context register packets can include information regarding a color format. In some aspects of context register packets, there can be a bit or bits that indicate which workload belongs to a context register. Also, there can be multiple functions or programming running at the same time and/or in parallel. For example, functions or programming can describe a certain operation, e.g., the color mode or color format. Accordingly, a context register can define multiple states of a GPU.

Context states can be utilized to determine how an individual processing unit functions, e.g., a vertex fetcher (VFD), a vertex shader (VS), a shader processor, or a geometry processor, and/or in what mode the processing unit functions. In order to do so, GPUs can use context registers and programming data. In some aspects, a GPU can generate a workload, e.g., a vertex or pixel workload, in the pipeline based on the context register definition of a mode or state. Certain processing units, e.g., a VFD, can use these states to determine certain functions, e.g., how a vertex is assembled. As these modes or states can change, GPUs may need to change the corresponding context. Additionally, the workload that corresponds to the mode or state may follow the changing mode or state.

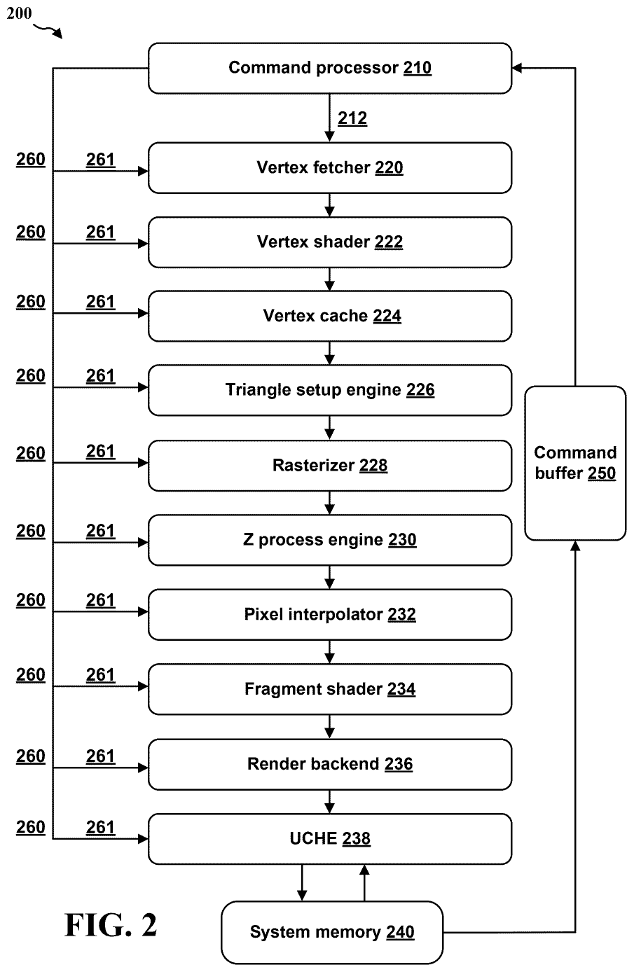

FIG. 2 illustrates an example graphics processor 200 in accordance with one or more techniques of this disclosure. The graphics processor 200 may include a GPU. As shown in FIG. 2, graphics processor 200 includes command processor (CP) 210, draw call packets 212, VFD 220, VS 222, vertex cache (VPC) 224, triangle setup engine (TSE) 226, rasterizer (RAS) 228, Z process engine (ZPE) 230, pixel interpolator (PI) 232, fragment shader (FS) 234, render backend (RB) 236, L2 cache (UCHE) 238, and system memory 240. Although FIG. 2 displays that graphics processor 200 includes processing units 220-238, graphics processor 200 can include a number of additional processing units. Additionally, processing units 220-238 are merely an example and any combination or order of processing units can be used by GPUs according to the present disclosure. Graphics processor 200 also includes command buffer 250, context register packets 260, and context states 261.

As shown in FIG. 2, a GPU can utilize a CP, e.g., CP 210, or hardware accelerator to parse a command buffer into context register packets, e.g., context register packets 260, and/or draw call data packets, e.g., draw call packets 212. The CP 210 can then send the context register packets 260 or draw call data packets 212 through separate paths to the processing units or blocks in the GPU. Further, the command buffer 250 can alternate different states of context registers and draw calls. For example, a command buffer can simultaneously store the following information: context register of context N, draw call(s) of context N, context register of context N+1, and draw call(s) of context N+1.

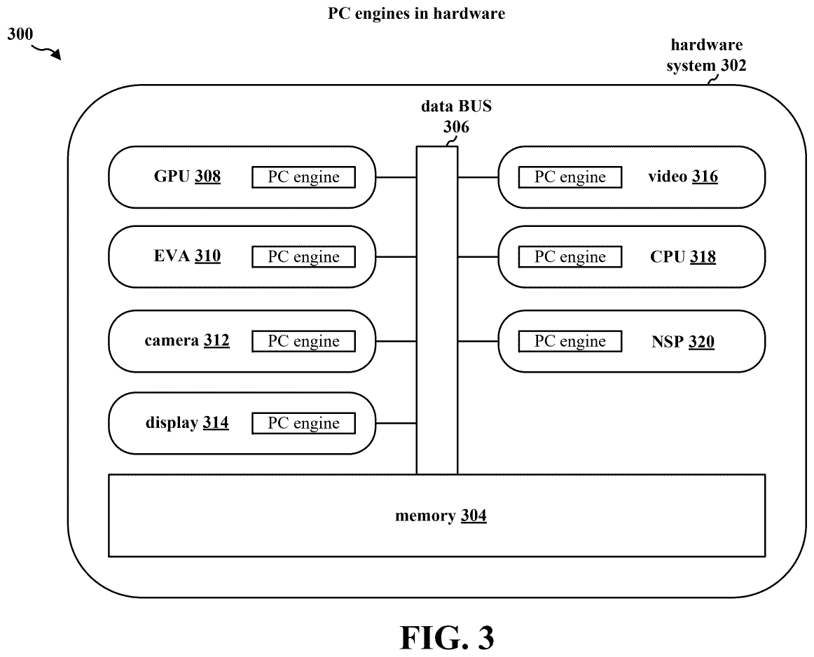

FIG. 3 is a diagram 300 of a hardware system 302, for example a computer desktop or mobile device, having a memory 304 and a data bus 306 which various hardware components may utilize to exchange data. The hardware system 302 may be any system on a chip (SoC) that utilizes a memory bandwidth compression scheme. The memory 304 may be any transitory or non-transitory memory, for example double data rate (DDR) memory or a flash drive. The hardware system 302 may have hardware components, such as a GPU 308, an enhanced video analytics (EVA) 310, a camera 312, a display 314, a video engine 316, a CPU 318, and/or a neural signal processor 320. A hardware component may output data to the data bus 306, for example to store data on the memory 304 or to send data to another hardware component to process. A hardware component may also obtain data from the data bus 306, for example by fetching data saved on the memory 304, or by obtaining data output by another hardware component. In order to conserve bandwidth of the data bus 306, at least one of the hardware components may have a PC engine that encodes, or compresses, data that is output to the data bus 306, and decodes, or decompresses, data that is obtained from the data bus 306. While the hardware system 302 is illustrated here having multiple PC engines distributed among hardware components, in some aspects a subset of the hardware components of a hardware system 302 may have a PC engine, or a hardware system 302 may have a single PC engine associated with a memory, such that any time data is stored on the memory a PC engine compresses the data, and any time data is fetched from the memory the PC engine decompresses the data. The PC engine may compress surfaces stored in the memory 304 and decompress surfaces fetched from the memory 304, which may be ubiquitous at a system level between hardware components.

A PC engine may also be referred to as a universal bandwidth compression (UBWC) engine, which may be configured to compress visual data transferred using the data bus 306 (e.g., between the memory 304 and hardware components) to save on power consumption and bandwidth resources. The visual data may also be referred to as a set of surface data. A PC engine may be configured to provide different levels of compression, for example a lossless compression that provides a comparatively small amount of compression without reducing the quality of the set of surface data, or a lossy compression that provides a comparatively greater amount of compression while reducing the quality or resolution of the set of surface data. A PC engine may be used to provide multiple levels of lossy compression. A first level of lossy compression may provide a comparatively small amount of compression while reducing the quality of the set of surface data by a comparatively small amount, and a second level of lossy compression may provide a comparatively larger amount of compression while reducing the quality of the set of surface data by a comparatively larger amount. PC engines may improve compression efficiency as compared with compression systems that do not provide multiple levels of lossy compression, as a compression level may be selected based on a rate-distortion (RD) performance.

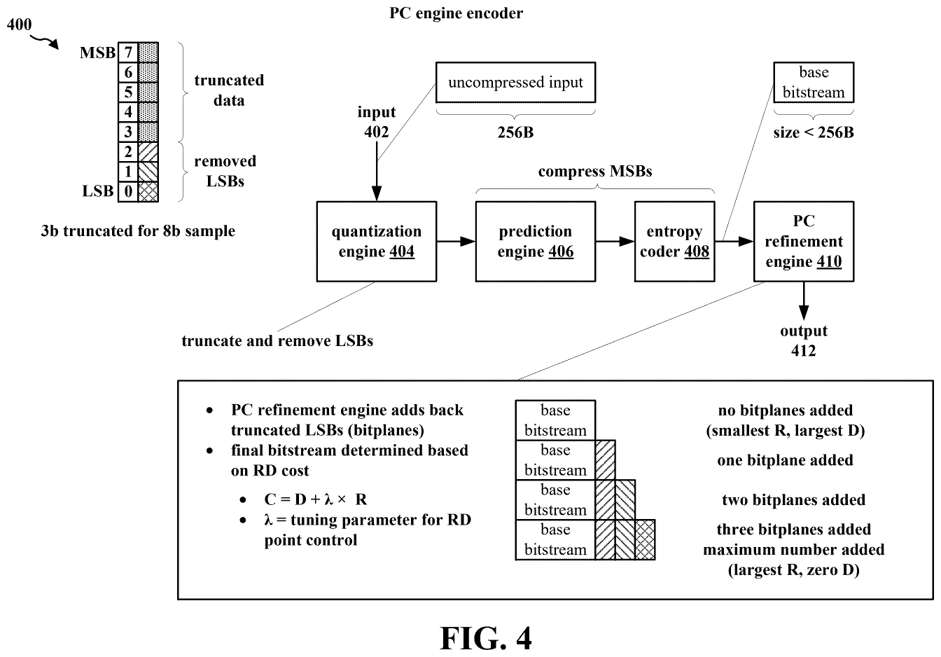

FIG. 4 is a diagram 400 illustrating an exemplary encoder of a PC engine, in accordance with one or more techniques of this disclosure. The encoder may be configured to obtain an input 402 of a set of surface data that is not compressed. A quantization engine 404 may be configured to truncate and remove a set of least significant bits (LSBs) from the input 402. The encoder may compress the truncated input via a prediction engine 406 and an entropy coder 408, for example by applying vertex prediction on the truncated input and encoding the residuals between the predicted and accurate coordinates. The prediction engine 406 may use any form of spatial prediction (e.g., string prediction (SP), cross component prediction (CCP)) using neighbor samples to predict current samples, while the entropy coder 408 may signal the residuals of the prediction engine 406. The entropy coder 408 may perform block fixed length coding (BFLC) on the predicted samples. The entropy coder 408 may output a base bitstream, which may include the entry-coded samples as well as headers and syntax going into the bitstream. The PC refinement engine 410 may then analyze the RD cost for adding each bitplane to the base bitstream, and select a number of bitplanes to add which is associated with the lowest RD cost based on a tuning parameter. The tuning parameter may be defined by a user of the system to tweak the optimal RD cost based on a level of resolution decline that is noticeable to the user of the system.

As an example, the input 402 may be a bitstream of 256 bytes of data, which represents a set of surface data, or visual data. The quantization engine 404 may remove the three LSBs from every eight bits of data, such that, for every eight-bit (8b) sample, the five most significant bits (MSBs) are preserved while the three LSBs are removed. As such, the truncated uncompressed input data may have a size of 160 byes. The prediction engine 406 and entropy coder 408 may compress the truncated uncompressed input data to have a size that is less than 256 bytes, such as 120 bytes. While this base bitstream may be output as-is, the distortion (D) associated with the base bitstream by itself may be quite large, and the resolution may suffer. The PC refinement engine may calculate the RD cost C based on the formula C=D+λ×R, where D represents the amount of distortion of the base bitstream by itself, R represents the rate of compression (e.g., compression ratio expressed in terms of size of the output 412 divided by the size of the input 402), and λ represents a user-defined parameter for RD point control. A user may adjust the value of the λ tuning parameter to adjust the weight between R and D. The PC refinement engine may calculate the RD cost C for the base bitstream by itself as the output 412, which may have the smallest R and the largest D, the RD cost C for the base bitstream plus one bitplane of a single bit per sample added to the bitstream, the RD cost C for the base bitstream plus two bitplanes of two bits per sample added to the bitstream, and the RD cost C for the base bitstream plus three bitplanes of three bits per sample added to the bitstream, which may have the largest R and zero D (i.e., lossless compression). The PC refinement engine 410 may select a number of bitplanes to add which are associated with the lowest calculated RD cost, and may add that number of bitplanes to the base bitstream in an uncompressed format (i.e., without any prediction or entropy encoding performed on the added bitplanes). In other words, the PC refinement engine 410 may perform a rate distortion optimization (RDO) to determine the most efficient PC level to use for the refined bitstream, or the output 412. The output 412 may be an output bitstream, for example a set of pulse code modulation (PCM) bits output to a data bus.

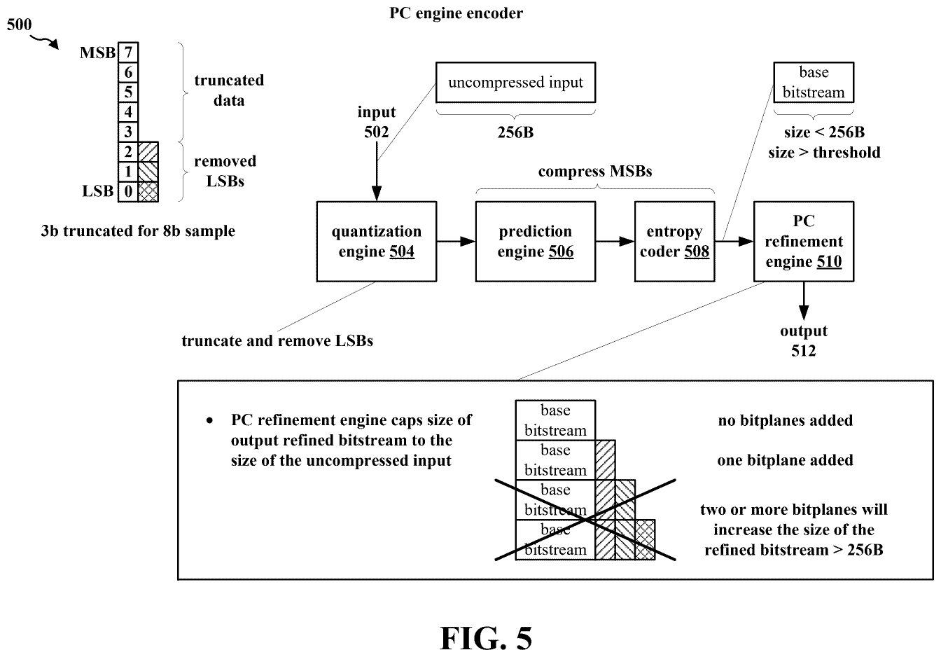

FIG. 5 is a diagram 500 illustrating an exemplary encoder of a PC engine, in accordance with one or more techniques of this disclosure. Similar to the encoder in FIG. 4, the encoder may be configured to obtain an input 502 of a set of surface data that is not compressed. A quantization engine 504 may be configured to truncate and remove a set of LSBs from the input 502, for example every 3 LSBs of an 8b sample. The encoder may compress the truncated input via a prediction engine 506 and an entropy coder 508. The entropy coder 508 may output a base bitstream, which may include the entry-coded samples as well as headers and syntax going into the bitstream. However, the base bitstream generated by the entropy coder 508 may be too large to accommodate adding two or three bitplanes. In other words, adding two or three bitplanes to the base bitstream may cause the output 512 to exceed the uncompressed input size. For example, if the uncompressed input size is 256 B, adding two or three bitplanes to the base bitstream may cause the output 512 to exceed 256 B. In another aspect, the encoder may compare the base bitstream to a threshold value, and may refrain from calculating an RD cost of adding two or three bitplanes in response to the size of the base bitstream being greater than or equal to the threshold value. The PC refinement engine 510 may analyze the RD cost for outputting the base bitstream as-is, and the RD cost for outputting the base bitstream with a single bitplane, and select a number of bitplanes (e.g., either 0 or 1) to add which is associated with the lowest calculated RD cost. In this aspect, the PC refinement engine 510 may refrain from considering a lossless compression level (i.e., adding three bitplanes to the base bitstream), as the lossless compression level may exceed the size of the uncompressed input size.

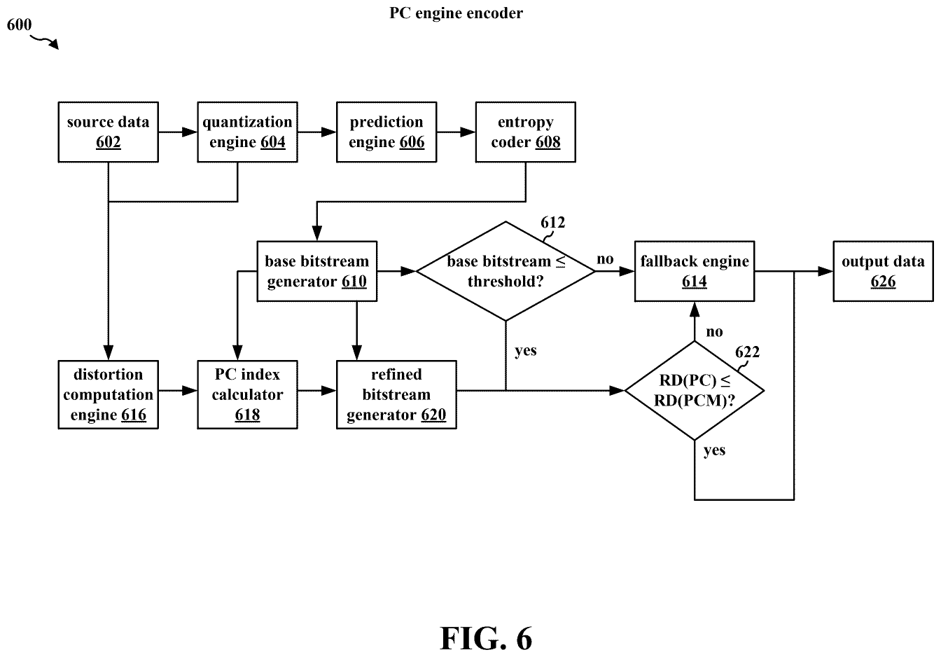

FIG. 6 is a diagram 600 illustrating an exemplary encoder of a PC engine, in accordance with one or more techniques of this disclosure. The encoder may be configured to encode a source data 602, which may include any visual data, such as a set of surfaces. The quantization engine 604 may quantize the source data 602 using a specified quantization factor referred to as QP_{pc}. The encoder may compress the truncated samples via a prediction engine 606 and an entropy coder 608. The base bitstream generator 610 may generate the base bitstream, which may include the entropy-coded samples as well as headers and syntax going into the bitstream. At 612, the encoder may determine if the generated base bitstream exceeds a threshold value (e.g., 1024 bits). The threshold value may also be referred to as a PCM threshold, which may be a maximum bandwidth for a PCM bitstream to transmit during a period of time (e.g., per second). If the base bitstream is greater or equal to the threshold value, then a fallback engine 614 may guarantee a rate constraint by outputting a lossy PCM fallback as the output data 626. For example, the fallback engine 614 may output the truncated samples generated by the quantization engine 604 without any entropy coding as the output data 626.

If the base bitstream is less than or equal to the threshold value, then the encoder may proceed with PC refinement. A distortion computation engine 616 may calculate the distortion D created by the original quantization by QP_{pc}. In some aspects, the distortion may be calculated as the sum of all of the LSBs in the original data that were removed by the quantization process at the quantization engine 604. The PC index calculator 618 may select a quantity of bitplanes to send as refinement bits at the end of the syntax. The refined bitstream generator 620 may combine the base bitstream generated by the base bitstream generator 610 and the refinement bits selected by the PC index calculator 618 as a refined bitstream. At 622, the encoder may compare the calculated RD of the refined bitstream generated by the refined bitstream generator 620 as compared with the calculated RD of a lossy PCM fallback. If the calculated RD of the refined bitstream is greater than or equal to the calculated RD of the lossy PCM fallback, the fallback engine 614 may output the lossy PCM fallback as the output data 626. If the calculated RD of the refined bitstream is less than or equal to the calculated RD of the lossy PCM fallback, the encoder may output the predicted refined bitstream as the output data 626.

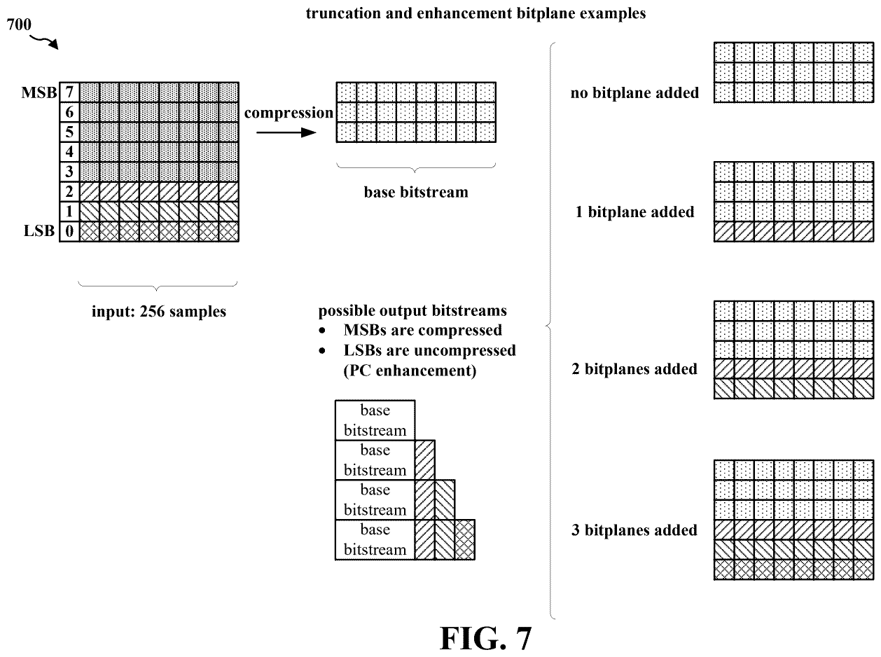

FIG. 7 is a diagram 700 of exemplary input and output bitstreams for a PC encoder, in accordance with one or more techniques of this disclosure. The uncompressed input bitstream may include 256 8b samples. A quantizer may truncate the three LSBs of each of the 256 8b samples, and may compress the truncated input data to generate a base bitstream. The base bitstream may include 256 compressed samples. The base bitstream with one bitplane added may include a refined bitstream of 256 compressed samples followed by a single bitplane including one bit per sample. The base bitstream with two bitplanes added may include a refined bitstream of 256 compressed samples followed by two bitplanes including two bits per sample The base bitstream with three bitplanes added may include a refined bitstream of 256 compressed samples followed by three bitplanes including three bits per sample.

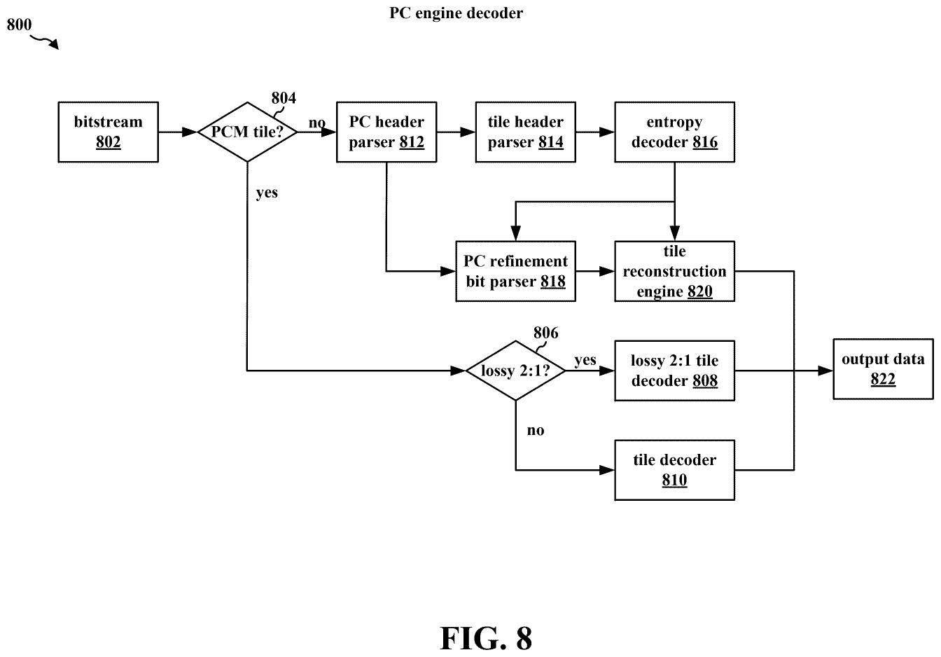

FIG. 8 is a diagram 800 illustrating an exemplary decoder of a PC engine, in accordance with one or more techniques of this disclosure. The bitstream 802 may include a set of PCM bits that are received by the decoder. At 804, the decoder may determine if the bitstream 802 includes a PCM tile. If the bitstream 802 includes a PCM tile, then there may not be any PC-related syntax in that portion of the bitstream 802. In other words, the portion of the bitstream that includes the PCM tile may use a lossy PCM fallback scheme. At 806, the decoder may determine if the PCM tile is a lossy 2:1 tile. If the codec operates in a lossy 2:1 mode (i.e., the compression ratio is 2:1), the PCM signal may correspond to a lossy PCM tile where the target compression rate of 2:1 is guaranteed. The PCM tile may include half of the bits (e.g., the MSB half of the bits). The lossy 2:1 tile decoder 808 may decode the lossy PCM tile by appending a generic half to the PCM tile, for example adding LSBs that are all 0s, all 1s, or which alternate between 0 and 1. The lossy 2:1 tile decoder 808 may output the reconstructed bitstream as the output data 822. If the codec does not operate in a lossy 2:1 mode, the PCM signal may correspond to a lossless PCM where the bitstream 802 includes all bits. In other words, the tile may be lossless. The tile decoder 810 may decode the lossless PCM signal and output the decoded signal as the output data 822.

If the bitstream 802 does not include a PCM tile, the PC header parser 812 may parse the bitstream 802 to read data indicators of the PC header. Due to asymmetric design, the complexity of the decoder may be less than the complexity of the encoder. The encoder may be configured to determine the number of refinement bits to transmit by calculating each bitplane configuration, while the decoder may be configured to simply parse the number of refinement bits from the PC header. The tile header parser 814 and the entropy decoder 816 may decode the entropy coded base bitstream. The PC refinement bit parser 818 may parse the PC refinement bits from the bitstream 802 based on the number of refinement bits indicated in the PC header. The tile reconstruction engine 820 may add the parsed PC refinement bits back to the decoded signal to generate a reconstructed signal. The tile reconstruction engine 820 may output the reconstructed signal as the output data 822.

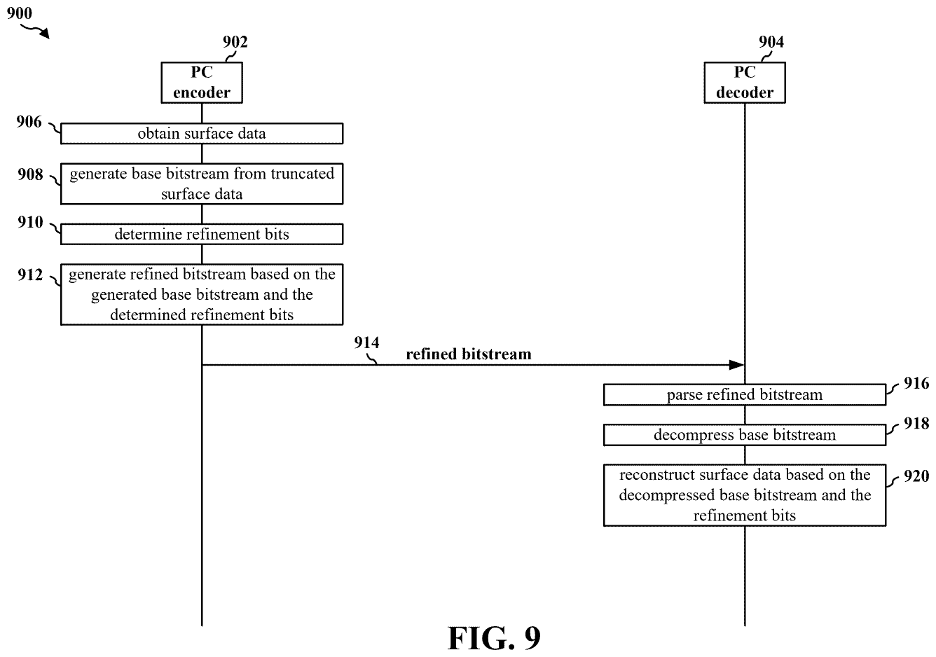

FIG. 9 is a call flow diagram 900 illustrating example communications between a PC encoder 902 and a PC decoder 904 in accordance with one or more techniques of this disclosure. At 906, the PC encoder 902 may obtain a set of surface data, for example from a hardware component transmitting an indication to store the set of surface data on a DDR memory. At 908, the PC encoder 902 may generate a base bitstream from truncated surface data. For example, the PC encoder 902 may perform quantization on the surface data obtained at 906, and may then perform prediction and entropy coding on the quantized data. At 910, the PC encoder 902 may determine a number of refinement bits to add to the base bitstream. The PC encoder 902 may determine the number of refinement bits by calculating an RD cost for each of the base bitstream, and each bitplane that may be added to the base bitstream without exceeding a threshold value, and may then select the number of refinement bits based on which calculated RD cost has the lowest value. At 912, the PC encoder 902 may generate refined bitstream based on the generated base bitstream and the determined refinement bits. The generated refined bitstream may be a set of PCM bits. The PC encoder 902 may output an indication 914 of the refined bitstream, for example to a data bus for storage on a DDR memory or for directing to another hardware component.

The PC decoder 904 may obtain the indication 914 of the refined bitstream. For example, the PC decoder 904 may fetch data from a DDR memory or may obtain a bitstream from another hardware component. At 916, the PC decoder 904 may parse the refined bitstream. The PC decoder 904 may determine how many refinement bits the refined bitstream has. At 918, the PC decoder 904 may decompress the base bitstream to obtain uncompressed truncated data. At 920, the PC decoder 904 may reconstruct surface data based on the decompressed base bitstream and the refinement bits by adding the refinement bits to the bitstream decompressed at 918.

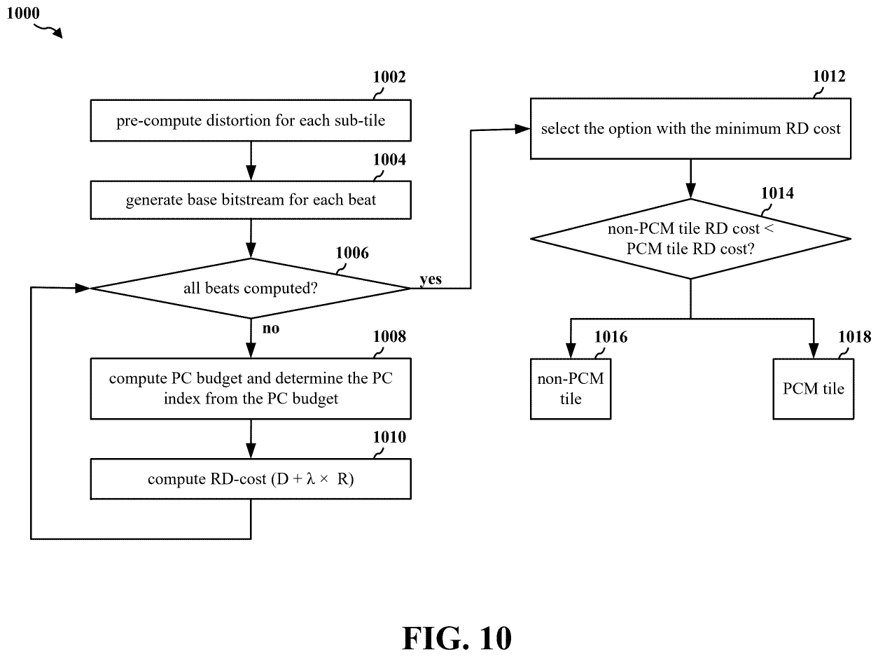

FIG. 10 is a flowchart 1000 of an example method of graphics processing in accordance with one or more techniques of this disclosure. The flowchart 1000 may describe a method of performing PC encoding on a set of surface data.

At 1002, the encoder may pre-compute a distortion for each sub-tile. For example, referring to FIG. 9, the PC encoder 902 may perform 1002 at 910 by calculating the distortion for each sub-tile. A subtile may be a defined portion of a tile. A tile may be separated into a plurality of subtiles via spatial partitioning of the tile, or via splitting the tile into its constituent components. The PC encoder 902 may calculate distortion for both PCM and non-PCM tiles.

The PC encoder 902 may pre-compute the distortion in parallel with an entropy coding path, which may include truncation, prediction, and BFLC. The distortion term D may represent the total distortion accumulated for all samples within a given tile for a specified QP_{pc} value.

At 1004, the encoder may generate a base bitstream for each beat. For example, referring to FIG. 9, the PC encoder 902 may perform 1004 at 908 to generate a base bitstream for each beat. A beat may be defined as a unit for minimum access length (MAL). For example, one beat may include 256 bits.

At 1006, the encoder may determine whether all beats are computed. In other words, 1006 may represent a for loop that iterates through computations for each generated base bitstream for each beat, and completes when all beats are computed.

At 1008, the encoder may compute a PC budget and determine a PC index from the PC budget. For example, referring to FIG. 9, the PC encoder 902 may perform 1008 at 910 to compute a PC budget and determine the PC index from the PC budget. The PC encoder 902 may determine the number of refinement bits to add to the bitstream based on an available bit budget. The PC encoder 902 may calculate the available bit budget based on the base bitstream. For example, in a lossy 2:1 footprint mode, a maximum of four beats may be available per tile, as the other four beats are removed. If the base bitstream is 800 bits and a PCM threshold is 1024 bits, the available bit budget may be 1024−800=224 bits. To minimize latency, the PC encoder 902 may not apply entropy coding to the refinement bits.

At 1010, the encoder may compute RD cost for each PC encoding level, for example for transmitting the base bitstream by itself, and for transmitting the base bitstream with various numbers of bitplanes up until a threshold level (e.g., transmitting all of the available bitplanes, transmitting a maximum number of bitplanes up to a PCM threshold). For example, referring to FIG. 9, the PC encoder 902 may perform 1010 at 910 to compute the RD cost for each PC encoding level.

At 1012, the encoder may select the option with the minimum RD cost. For example, referring to FIG. 9, the PC encoder 902 may perform 1012 to select a PC encoding level with the minimum RD cost.

At 1014, the encoder may determine if the RD cost of the non-PCM tile is less than the RD cost of the fallback PCM tile. If the encoder determines that the RD cost of the non-PCM tile is less than the RD cost of the fallback PCM tile, then at 1016, the encoder may output the non-PCM tile. If the encoder determines that the RD cost of the fallback PCM tile is less than or equal to the RD cost of the non-PCM tile, then at 1018, the encoder may output the PCM tile.

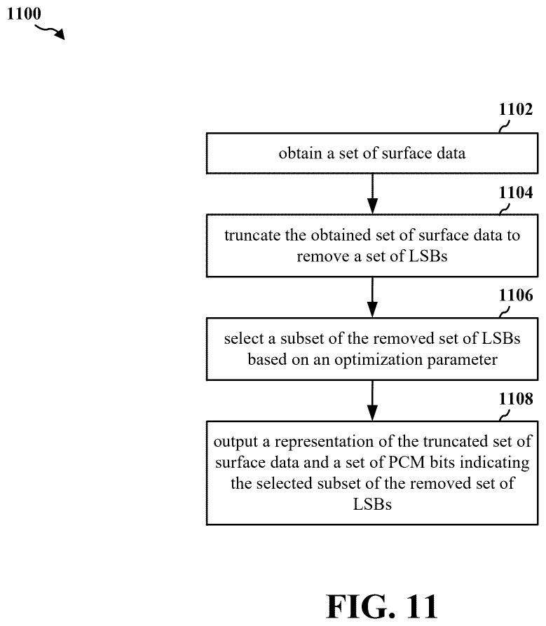

FIG. 11 is a flowchart 1100 of an example method of graphics processing in accordance with one or more techniques of this disclosure. The method may be performed by an apparatus, such as an apparatus for graphics processing, a SoC, a GPU, a CPU, a wireless communication device, and the like, as used in connection with the aspects of FIGS. 1-10.

At 1102, the apparatus may obtain a set of surface data. For example, referring to FIG. 9, the PC encoder 902 may obtain a set of surface data. Moreover, 1102 may be performed by the PC engine 198 in FIG. 1.

At 1104, the apparatus may truncate the obtained set of surface data to remove a set of LSBs. For example, referring to FIG. 9, the PC encoder 902 may truncate the obtained set of surface data to remove a set of LSBs. Moreover, 1104 may be performed by the PC engine 198 in FIG. 1.

At 1106, the apparatus may select a subset of the removed set of LSBs based on an optimization parameter. For example, referring to FIG. 9, the PC encoder 902 may select a subset of the removed set of LSBs based on an optimization parameter. Moreover, 1106 may be performed by the PC engine 198 in FIG. 1.

At 1108, the apparatus may output a representation of the truncated set of surface data and a set of PCM bits indicating the selected subset of the removed set of LSBs. For example, referring to FIG. 9, the PC encoder 902 may output a representation of the truncated set of surface data and a set of PCM bits indicating the selected subset of the removed set of LSBs. Moreover, 1108 may be performed by the PC engine 198 in FIG. 1.

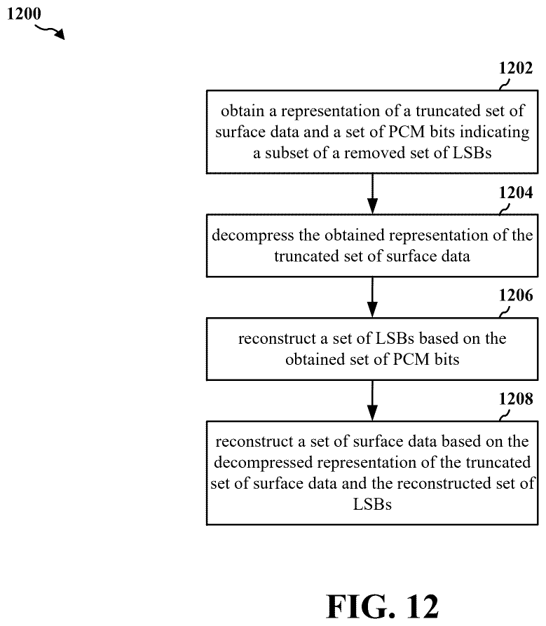

FIG. 12 is a flowchart 1200 of an example method of graphics processing in accordance with one or more techniques of this disclosure. The method may be performed by an apparatus, such as an apparatus for graphics processing, a SoC, a GPU, a CPU, a wireless communication device, and the like, as used in connection with the aspects of FIGS. 1-10.

At 1202, the apparatus may obtain a representation of a truncated set of surface data and a set of PCM bits indicating a subset of a removed set of LSBs. For example, referring to FIG. 9, the PC decoder 904 may obtain a representation of a truncated set of surface data and a set of PCM bits indicating a subset of a removed set of LSBs. Moreover, 1202 may be performed by the PC engine 198 in FIG. 1.

At 1204, the apparatus may decompress the obtained representation of the truncated set of surface data. For example, referring to FIG. 9, the PC decoder 904 may decompress the obtained representation of the truncated set of surface data. Moreover, 1204 may be performed by the PC engine 198 in FIG. 1.

At 1206, the apparatus may reconstruct a set of LSBs based on the obtained set of PCM bits. For example, referring to FIG. 9, the PC decoder 904 may reconstruct a set of LSBs based on the obtained set of PCM bits. Moreover, 1206 may be performed by the PC engine 198 in FIG. 1.

At 1208, the apparatus may reconstruct a set of surface data based on the decompressed representation of the truncated set of surface data and the reconstructed set of LSBs. For example, referring to FIG. 9, the PC decoder 904 may reconstruct a set of surface data based on the decompressed representation of the truncated set of surface data and the reconstructed set of LSBs. Moreover, 1208 may be performed by the PC engine 198 in FIG. 1.

In configurations, a method or an apparatus for graphics processing is provided. The apparatus may be a GPU, a CPU, or some other processor that may perform graphics processing. In aspects, the apparatus may be the processing unit 120 within the device 104, or may be some other hardware within the device 104 or another device. The apparatus may include means for obtaining a set of surface data. The apparatus may further include means for truncating the obtained set of surface data to remove a set of LSBs. The apparatus may further include means for selecting a subset of the removed set of LSBs based on an optimization parameter. The apparatus may further include means for outputting a representation of the truncated set of surface data and a set of PCM bits indicating the selected subset of the removed set of LSBs. The apparatus may further include means for obtaining a representation of a truncated set of surface data and a set of PCM bits indicating a subset of a removed set of LSBs. The apparatus may further include means for decompressing the obtained representation of the truncated set of surface data. The apparatus may further include means for reconstructing a set of LSBs based on the obtained set of PCM bits. The apparatus may further include means for reconstructing a set of surface data based on the decompressed representation of the truncated set of surface data and the reconstructed set of LSBs. The means may include the PC engine 198 in FIG. 1

It is understood that the specific order or hierarchy of blocks/steps in the processes, flowcharts, and/or call flow diagrams disclosed herein is an illustration of example approaches. Based upon design preferences, it is understood that the specific order or hierarchy of the blocks/steps in the processes, flowcharts, and/or call flow diagrams may be rearranged. Further, some blocks/steps may be combined and/or omitted. Other blocks/steps may also be added. The accompanying method claims present elements of the various blocks/steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, where reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.

Unless specifically stated otherwise, the term “some” refers to one or more and the term “or” may be interpreted as “and/or” where context does not dictate otherwise. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor (i.e., a set of one or more processors P) is configured to perform a set of functions F, each processor of P may be configured to perform a subset S of F, where S ⊆F. Accordingly, each processor of the at least one processor may be configured to perform a particular subset of the set of functions, where the subset is the full set, a proper subset of the set, or an empty subset of the set. A proper subset of a set has one or more elements of the full set, but does not include the full set itself. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.” Unless stated otherwise, the phrase “a processor” may refer to “any of one or more processors” (e.g., one processor of one or more processors, a number (greater than one) of processors in the one or more processors, or all of the one or more processors) and the phrase “a memory” may refer to “any of one or more memories” (e.g., one memory of one or more memories, a number (greater than one) of memories in the one or more memories, or all of the one or more memories).

In one or more examples, the functions described herein may be implemented in hardware, software, firmware, or any combination thereof. For example, although the term “processing unit” has been used throughout this disclosure, such processing units may be implemented in hardware, software, firmware, or any combination thereof. If any function, processing unit, technique described herein, or other module is implemented in software, the function, processing unit, technique described herein, or other module may be stored on or transmitted over as one or more instructions or code on a computer-readable medium.

Computer-readable media may include computer data storage media or communication media including any medium that facilitates transfer of a computer program from one place to another. In this manner, computer-readable media generally may correspond to: (1) tangible computer-readable storage media, which is non-transitory; or (2) a communication medium such as a signal or carrier wave. Data storage media may be any available media that can be accessed by one or more computers or one or more processors to retrieve instructions, code, and/or data structures for implementation of the techniques described in this disclosure. By way of example, and not limitation, such computer-readable media may include RAM, ROM, EEPROM, compact disc-read only memory (CD-ROM), or other optical disk storage, magnetic disk storage, or other magnetic storage devices. Disk and disc, as used herein, includes compact disc (CD), laser disc, optical disc, digital versatile disc (DVD), floppy disk, and Blu-ray disc, where disks usually reproduce data magnetically, while discs usually reproduce data optically with lasers. Combinations of the above should also be included within the scope of computer-readable media. A computer program product may include a computer-readable medium.

The techniques of this disclosure may be implemented in a wide variety of devices or apparatuses, including a wireless handset, an integrated circuit (IC) or a set of ICs, e.g., a chip set. Various components, modules or units are described in this disclosure to emphasize functional aspects of devices configured to perform the disclosed techniques, but do not necessarily need realization by different hardware units. Rather, as described above, various units may be combined in any hardware unit or provided by a collection of inter-operative hardware units, including one or more processors as described above, in conjunction with suitable software and/or firmware. Accordingly, the term “processor,” as used herein may refer to any of the foregoing structure or any other structure suitable for implementation of the techniques described herein. Also, the techniques may be fully implemented in one or more circuits or logic elements.

An indication of a set of data may include the data itself, or a reference to the data, for example a memory address where the data may be retrieved by the receiving entity, or an index to a set of data (e.g., an index of 1 that represents the series of bits 1100101). A single indication may also include a set of indications, for example an array of memory addresses or a plurality of index references.

The following aspects are illustrative only and may be combined with other aspects or teachings described herein, without limitation.
Aspect 1 is a method of graphics processing, comprising: obtaining a set of surface data; truncating the obtained set of surface data to remove a set of least significant bits (LSBs); selecting a subset of the removed set of LSBs based on an optimization parameter; and outputting a representation of the truncated set of surface data and a set of pulse code modulation (PCM) bits indicating the selected subset of the removed set of LSBs.
Aspect 2 is the method of aspect 1, further comprising: selecting the optimization parameter from a plurality of optimization parameters based on a distortion and a rate associated with each corresponding optimization parameter of the plurality of optimization parameters.
Aspect 3 is the method of aspect 2, further comprising: receiving an indication of a tuning parameter, wherein selecting the optimization parameter from the plurality of optimization parameters further comprises: selecting the optimization parameter from the plurality of optimization parameters further based on the received indication of the tuning parameter.
Aspect 4 is the method of aspect 3, wherein selecting the optimization parameter from the plurality of optimization parameters further based on the received indication of the tuning parameter comprises: determining a cost for each optimization parameter of the plurality of optimization parameters based on the distortion, the rate, and the tuning parameter; and selecting the optimization parameter based on the determined cost for each optimization parameter of the plurality of optimization parameters.
Aspect 5 is the method of any of aspects 1 to 4, further comprising: obtaining a second set of surface data; truncating the obtained second set of surface data to remove a second set of least significant bits (LSBs); and outputting a second representation of the obtained second set of surface data based on a determination that a size of the truncated second set of surface data does not satisfy a PCM threshold size.
Aspect 6 is the method of any of aspects 1 to 5, wherein outputting the representation of the truncated set of surface data and the set of PCM bits comprises: outputting a bitstream comprising a progressive coding (PC) PC header, the representation of the truncated set of surface data, and the set of PCM bits, wherein the PC header comprises an indication of the optimization parameter.
Aspect 7 is the method of any of aspects 1 to 6, wherein selecting the subset of the removed set of LSBs based on the optimization parameter comprises: obtaining an indication of a first priority associated with a first tile of the set of surface data and an indication of a second priority associated with a second tile of the set of surface data; and selecting a first optimization parameter associated with the first tile based on the first priority and a second optimization parameter associated with the second tile based on the second priority, wherein the first optimization parameter is associated with a different number of removed LSBs than the second optimization parameter.
Aspect 8 is the method of any of aspects 1 to 7, further comprising: entropy encoding the truncated set of surface data before outputting the representation of the truncated set of surface data.
Aspect 9 is the method of aspect 8, further comprising: refraining from entropy encoding the set of PCM bits.
Aspect 10 is the method of either of aspects 8 or 9, further comprising: performing prediction on the truncated set of surface data before entropy encoding the truncated set of surface data.
Aspect 11 is a method of graphics processing, comprising: obtaining a representation of a truncated set of surface data and a set of pulse code modulation (PCM) bits indicating a subset of a removed set of LSBs; decompressing the obtained representation of the truncated set of surface data; reconstructing a set of LSBs based on the obtained set of PCM bits; and reconstructing a set of surface data based on the decompressed representation of the truncated set of surface data and the reconstructed set of LSBs.
Aspect 12 is a method of aspect 11, further comprising: obtaining a second representation of a second set of surface data, wherein the second representation does not comprise compressed data
Aspect 13 is a method of either of aspects 11 or 12, wherein obtaining the representation of the truncated set of surface data and the set of PCM bits comprises: obtaining a bitstream comprising a progressive coding (PC) PC header, the representation of the truncated set of surface data, and the set of PCM bits, wherein the PC header comprises an indication of an optimization parameter, wherein reconstructing the set of LSBs based on the obtained set of PCM bits comprises: reconstructing the set of LSBs further based on the optimization parameter.
Aspect 14 is a method of any of aspects 11 to 13, wherein the optimization parameter indicates a number of bitplanes per subtile of the bitstream, wherein reconstructing the set of LSBs further based on the optimization parameter comprises: reconstructing a number of bits equal to the number of bitplanes for each subtile of the bitstream
Aspect 15 is a method of any of aspects 11 to 14, further comprising: parsing the PC header to determine the indication of the optimization parameter before a reconstruction of the set of LSBs
Aspect 16 is a method of any of aspects 11 to 15, further comprising: entropy decoding the obtained representation of the truncated set of surface data before a decompression of the obtained representation of the truncated set of surface data
Aspect 17 is a method of aspect 16, further comprising: refraining from entropy decoding the obtained set of PCM bits
Aspect 18 is an apparatus for graphics processing including at least one processor coupled to a memory and configured to implement a method as in any of aspects 1-17
Aspect 19 may be combined with aspect 18 and includes that the apparatus is a wireless communication device.
Aspect 20 is an apparatus for graphics processing including means for implementing a method as in any of aspects 1-17.
Aspect 21 is a computer-readable medium (e.g., a non-transitory computer-readable medium) storing computer executable code, the code when executed by at least one processor causes the at least one processor to implement a method as in any of aspects 1-17.

Various aspects have been described herein. These and other aspects are within the scope of the following claims.

What is claimed is:

1. An apparatus for graphics processing, comprising:
a memory; and
a processor coupled to the memory and, based at least in part on information stored in the memory, the processor is configured to:
obtain a set of surface data;
truncate the obtained set of surface data to remove a set of least significant bits (LSBs);
select a subset of the removed set of LSBs based on an optimization parameter; and
output a representation of the truncated set of surface data and a set of pulse code modulation (PCM) bits indicating the selected subset of the removed set of LSBs.

2. The apparatus of claim 1, wherein the processor is further configured to:
select the optimization parameter from a plurality of optimization parameters based on a distortion and a rate associated with each corresponding optimization parameter of the plurality of optimization parameters.

3. The apparatus of claim 2, wherein the processor is further configured to:
receive an indication of a tuning parameter, wherein, to select the optimization parameter from the plurality of optimization parameters, the processor is configured to:
select the optimization parameter from the plurality of optimization parameters further based on the received indication of the tuning parameter.

4. The apparatus of claim 3, wherein, to select the optimization parameter from the plurality of optimization parameters further based on the received indication of the tuning parameter, the processor is configured to:
determine a cost for each optimization parameter of the plurality of optimization parameters based on the distortion, the rate, and the tuning parameter; and
select the optimization parameter based on the determined cost for each optimization parameter of the plurality of optimization parameters.

5. The apparatus of claim 1, wherein the processor is further configured to:
obtain a second set of surface data;
truncate the obtained second set of surface data to remove a second set of LSBs; and
output a second representation of the obtained second set of surface data based on a determination that a size of the truncated second set of surface data does not satisfy a PCM threshold size.

6. The apparatus of claim 1, wherein, to output the representation of the truncated set of surface data and the set of PCM bits, the processor is configured to:
output a bitstream comprising a progressive coding (PC) header, the representation of the truncated set of surface data, and the set of PCM bits, wherein the PC header comprises an indication of the optimization parameter.

7. The apparatus of claim 1, wherein, to select the subset of the removed set of LSBs based on the optimization parameter, the processor is configured to:
obtain an indication of a first priority associated with a first tile of the set of surface data and an indication of a second priority associated with a second tile of the set of surface data; and
select a first optimization parameter associated with the first tile based on the first priority and a second optimization parameter associated with the second tile based on the second priority, wherein the first optimization parameter is associated with a different number of removed LSBs than the second optimization parameter.

8. The apparatus of claim 1, wherein the processor is further configured to:
entropy encode the truncated set of surface data before outputting the representation of the truncated set of surface data.

9. The apparatus of claim 8, wherein the processor is further configured to:
refrain from entropy encoding the set of PCM bits.

10. The apparatus of claim 8, wherein the processor is further configured to:
perform prediction on the truncated set of surface data before entropy encoding the truncated set of surface data.

11. The apparatus of claim 1, wherein the apparatus comprises a wireless communication device.

12. An apparatus for graphics processing, comprising:
a memory; and
a processor coupled to the memory and, based at least in part on information stored in the memory, the processor is configured to:
obtain a representation of a truncated set of surface data and a set of pulse code modulation (PCM) bits indicating a subset of a removed set of LSBs;
decompress the obtained representation of the truncated set of surface data;
reconstruct a set of LSBs based on the obtained set of PCM bits; and
reconstruct a set of surface data based on the decompressed representation of the truncated set of surface data and the reconstructed set of LSBs.

13. The apparatus of claim 12, wherein the processor is further configured to:
obtain a second representation of a second set of surface data, wherein the second representation does not comprise compressed data.

14. The apparatus of claim 12, wherein, to obtain the representation of the truncated set of surface data and the set of PCM bits, the processor is configured to:
obtain a bitstream comprising a progressive coding (PC) PC header, the representation of the truncated set of surface data, and the set of PCM bits, wherein the PC header comprises an indication of an optimization parameter, wherein, to reconstruct the set of LSBs based on the obtained set of PCM bits, the processor is configured to:
reconstruct the set of LSBs further based on the optimization parameter.

15. The apparatus of claim 14, wherein the optimization parameter indicates a number of bitplanes per subtile of the bitstream, wherein, to reconstruct the set of LSBs further based on the optimization parameter, the processor is configured to:
reconstruct a number of bits equal to the number of bitplanes for each subtile of the bitstream.

16. The apparatus of claim 14, wherein the processor is further configured to:
parse the PC header to determine the indication of the optimization parameter before a reconstruction of the set of LSBs.

17. The apparatus of claim 12, wherein the processor is further configured to:
entropy decode the obtained representation of the truncated set of surface data before a decompression of the obtained representation of the truncated set of surface data.

18. The apparatus of claim 17, wherein the processor is further configured to:
refrain from entropy decoding the obtained set of PCM bits.

19. A method of graphics processing, comprising:
obtaining a set of surface data;
truncating the obtained set of surface data to remove a set of least significant bits (LSBs);
selecting a subset of the removed set of LSBs based on an optimization parameter; and
outputting a representation of the truncated set of surface data and a set of pulse code modulation (PCM) bits indicating the selected subset of the removed set of LSBs.

20. A method of graphics processing, comprising:
obtaining a representation of a truncated set of surface data and a set of pulse code modulation (PCM) bits indicating a subset of a removed set of LSBs;
decompressing the obtained representation of the truncated set of surface data;
reconstructing a set of LSBs based on the obtained set of PCM bits; and
reconstructing a set of surface data based on the decompressed representation of the truncated set of surface data and the reconstructed set of LSBs.
